(19) United States
(12) Patent Application Publication
(10) Pub. No.: US 2016/0218750 A1
(43) Pub. Date: Jul. 28, 2016

(54) PARITY CHECK CODE ENCODER

(71) Applicant: Empire Technology Development LLC, Wilmington, DE (US)

(72) Inventor: Xudong Ma, Clifton Park, NY (US)

(21) Appl. No.: 14/604,482

(22) Filed: Jan. 23, 2015

(51) Int. Cl. H03M 13/29

(52) U.S. Cl. CPC H03M 13/2942

(57) ABSTRACT

Technologies to encode and decode a message are disclosed herein. In some implementations, a low density parity check (“LDPC”) code base graph G(k) may be divided a number of times into a smaller LDPC code graph G(k−n). Data to be stored may be encoded according to the smaller LDPC code graph G(k−n) to generate an encoded message. The encoded message may thereafter be stored in a memory device such as a multi-level cell memory device.

### BACKGROUND

Unless otherwise indicated herein, the materials described in this section are not prior art to the claims in this application and are not admitted to be prior art by inclusion in this section.

Low-density parity check (LDPC) codes, which may be built upon iterative decoding principles, may be used in some error-control code methods. LDPC codes have found many applications ranging from wireless and satellite communications to computer data storage systems and others. For example, the LDPC codes are included in the IEEE 802.11n wireless standard and DVB-S2 satellite communication standard. There is a trend of adopting LDPC codes in flash memory systems. Types of flash memory receiving increasing usage may include, for example, multilayer cell (MLC) and three layer cell (TLC) memories. These flash memories may achieve lower price points compared with single level cell (SLC) type flash memories. However, these types of flash memories may be more error-prone and have much lower write endurance when compared to other types of memory.

### SUMMARY

Briefly stated, technologies are generally described herein to encode a message. In one example, a method is described. The method may include receiving an LDPC code based on a 2̂n-lift Tanner graph, receiving a 2̂n-lift Tanner graph information vector comprising 2̂n-lift Tanner graph information bits, and receiving a 2̂n-lift Tanner graph parity check vector comprising 2̂n-lift Tanner graph parity check bits.

The method may also include performing a decomposition process of the 2̂n-lift Tanner graph. The decomposition process may be performed by calculating a 2̂n−1 Tanner graph information vector comprising 2̂n−1 Tanner graph information bits on a 2̂n−1 Tanner graph of the 2̂n-lift Tanner graph using the 2̂n-lift Tanner graph information bits of the 2̂n-lift Tanner graph information vector. The decomposition process may continue by calculating a 2̂n−1 Tanner graph parity check vector comprising 2̂n−1 Tanner graph parity check bits on the 2̂n−1 Tanner graph of the 2̂n-lift Tanner graph using the 2̂n-lift Tanner graph parity check bits of the 2̂n-lift Tanner graph parity check vector. The decomposition process may be further continued by computing a 2̂n−1 Tanner graph codeword comprising 2̂n−1 Tanner graph codeword bits on the 2̂n−1 Tanner graph of the 2̂n-lift Tanner graph using the 2̂n−1 Tanner graph information vector and the 2̂n−1 Tanner graph parity check vector.

The method may continue by computing a 2̂n-lift Tanner graph codeword comprising 2̂n-lift Tanner graph codeword bits on the 2̂n-lift Tanner graph using a 2̂n-lift graph edge configuration, the 2̂n−1 Tanner graph codeword, the 2̂n-lift Tanner graph information vector, and the 2̂n-lift Tanner graph parity check vector.

In another example, a method is described. The method may include receiving a generalized information vector comprising information bits, receiving a generalized parity check vector, and calculating a covered information vector using the information bits of the received generalized information vector. The method may also include calculating a covered parity check vector using the received generalized parity check vector and computing a covered generalized codeword on a base graph of a 2-lift graph using the calculated covered information vector and the calculated covered parity check vector.

Crossing parameters may be calculated using the edge configuration of the 2-lift Tanner graph. A modified parity check vector may be calculated using a first copy of the base graph of the 2-lift graph, the calculated crossing parameters, the computed covered generalized codeword, and the received generalized parity check vector. A generalized codeword may be calculated using the base graph, the calculated modified parity check vector and the information bits, wherein the information bits are set to information bits in the first copy of the of the base graph of the 2-lift graph.

In a further example, a computer-readable storage medium is described. The computer-readable storage medium may include computer-executable instructions stored thereon which, in response to execution by a computer, cause the computer to perform a method to encode a message. The method may include receiving an LDPC code based on a 2̂n-lift Tanner graph, receiving a 2̂n-lift Tanner graph information vector comprising 2̂n-lift Tanner graph information bits, and receiving a 2̂n-lift Tanner graph parity check vector comprising 2̂n-lift Tanner graph parity check bits.

The method may also include performing a decomposition process of the 2̂n-lift Tanner graph. The decomposition process may be performed by calculating a 2̂n−1 Tanner graph information vector comprising 2̂n−1 Tanner graph information bits on a 2̂n−1 Tanner graph of the 2̂n-lift Tanner graph using the 2̂n-lift Tanner graph information bits of the 2̂n-lift Tanner graph information vector. The decomposition process may continue by calculating a 2̂n−1 Tanner graph parity check vector comprising 2̂n−1 Tanner graph parity check bits on the 2̂n−1 Tanner graph of the 2̂n-lift Tanner graph using the 2̂n-lift Tanner graph parity check bits of the 2̂n-lift Tanner graph parity check vector. The decomposition process may be further continued by computing a 2̂n−1 Tanner graph codeword comprising 2̂n−1 Tanner graph codeword bits on the 2̂n−1 Tanner graph of the 2̂n-lift Tanner graph using the 2̂n−1 Tanner graph information vector and the 2̂n−1 Tanner graph parity check vector.

The method may continue by computing a 2̂n-lift Tanner graph codeword comprising 2̂n-lift Tanner graph codeword bits on the 2̂n-lift Tanner graph using a 2̂n-lift graph edge configuration, the 2̂n−1 Tanner graph codeword, the 2̂n-lift Tanner graph information vector, and the 2̂n-lift Tanner graph parity check vector.

In a still further example, a method to store data is described. The method may include receiving the data to be encoded, receiving a low density parity check (“LDPC”) code based on a Tanner graph G(k), dividing the LDPC code a number of times into a data encoding on a smaller LDPC code graph G(k−n), and encoding the data according to the data encoding on the smaller LDPC code graph G(k−n) to generate an encoded message.

In an additional example, an encoder is described. The encoder may include a covered codeword processor unit, a modified codeword processor unit, and a divide and conquer unit coupled to the covered codeword processor unit and to the modified codeword processor unit. The divide and conquer unit may be operative to generate a first smaller sized problem instance, receive a first solution output result from the covered codeword processor unit, and generate a second smaller sized problem instance by use of the received first solution output result. The divide and conquer unit may be further operative to receive a second solution output result from the modified codeword processor unit, and generate a generalized codeword based on the received first solution output result and the received second solution output result.

The covered codeword processor unit may be operative to receive the generated first smaller sized problem instance from the divide and conquer unit, generate the first solution output result based on the generalized first smaller sized problem instance, and send the generated first solution output result to the divide and conquer unit. The modified codeword processor unit may be operative to receive the generated second smaller sized problem instance from the divide and conquer unit, and generate the second solution output result based on the received second smaller sized problem instance.

The foregoing Summary is illustrative only and is not intended to be in any way limiting. In addition to the illustrative aspects, embodiments, and features described above, further aspects, embodiments, and features will become apparent by reference to the Figures and the following Detailed Description.

### BRIEF DESCRIPTION OF THE FIGURES

The foregoing and other features of this disclosure will become more fully apparent from the following description and appended claims, taken in conjunction with the accompanying drawings. Understanding that these drawings depict only some embodiments in accordance with the disclosure and are, therefore, not to be considered limiting of its scope, the disclosure will be described with additional specificity and detail through use of the accompanying drawings, in which:

FIG. 1 is a block diagram illustrating an example of a memory system configured to implement low density parity check encoding;

FIG. 2 illustrates an example of a parity check equation that may be used as a basis for 2-lift based LDPC encoding;

FIG. 3 is an illustration providing an example of a parity check equation having numerical values;

FIG. 4 is an example of a Tanner graph representation of the parity check equation in FIG. 3;

FIG. 5 is an example of a Tanner graph resulting from a 2-lift of the Tanner graph of FIG. 4;

FIG. 6 is an illustration providing an example of a parity check equation that may be solved by decomposing a parity check equation into smaller encoding;

FIG. 7A is a flow diagram of an example encoding process;

FIG. 7B is a flow diagram of another example encoding process;

FIG. 8 is a block diagram illustrating an example encoder;

FIG. 9 is an illustration of an example of a hardware implementation to perform a method for LDPC decoding;

FIG. 10 is an example of a Tanner graph representation of the LDPC code of FIG. 9;

FIG. 11 is an illustration of an example of a check node unit;

FIG. 12 is an example of a variable node unit;

FIG. 13 is an illustration of an example of a memory block; and

FIG. 14 is a block diagram illustrating an example computing device that is arranged to implement various aspects of the presently disclosed subject matter,

all arranged according to at least some embodiments presented herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description and drawings are not meant to be limiting. Other embodiments may be utilized, and other changes may be made, without departing from the spirit or scope of the subject matter presented herein.

The aspects of the present disclosure, as generally described herein, and illustrated in the figures, can be arranged, substituted, combined, separated, and designed in a wide variety of different configurations, all of which are explicitly contemplated herein. Further, one or more components of various figures described below may not be included in the figure, for purposes of clarity or brevity. This should not be construed as a disclaimer or admission that the non-included components do not form part of the subject matter described herein. Additionally, one or more figures may use a “dashed” line as a border to visually encapsulate one or more components. Unless specifically described otherwise, the use of a dashed line is for purposes of illustration and does not necessarily reflect functional or physical boundaries.

This disclosure is generally drawn, inter alia, to technologies for an LDPC encoder for 2-lift based LDPC codes. In some implementations, the LDPC encoder may be used to encode data for storage in a memory. In some examples, the LDPC encoder may be configured to encode the data using an LDPC code. According to some configurations, the LDPC encoder may divide a Tanner graph G(k) of the LDPC code into smaller graphs G(k−1), where “G” identifies a graph as a Tanner graph and “k” represents the number of lifts of the Tanner graph. The LDPC encoder may further break down the smaller graphs G(k−1) into further smaller graphs G(k−n). The dividing process may continue until the sizes of the graphs are suitable for encoding according to various criteria such as encoding speed and complexity. In these examples, an encoding problem on a G(k) graph may be decomposed into two, or more, encoding problems on smaller G(k−n) graphs.

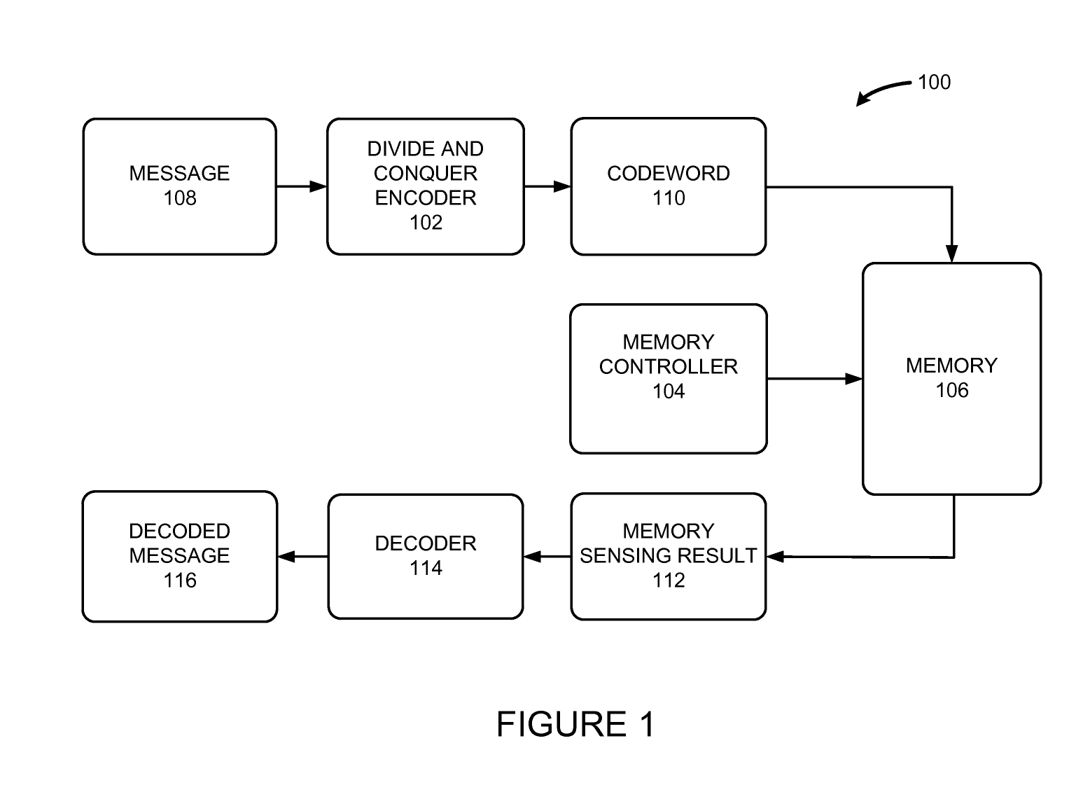

FIG. 1 is a block diagram illustrating an example of a memory system 100 configured to implement low density parity check encoding, arranged according to at least some embodiments presented herein. The memory system 100 may include a divide and conquer encoder 102, a memory controller 104, and a memory 106, all operatively coupled to each other. The divide and conquer encoder 102 may have a message 108 as an input and a codeword 110 as an output. The memory 106 may be configured to receive as an input the codeword 110 and to output a memory sensing result 112. A decoder 114 coupled to the memory 106 may receive the memory sensing result 112 as an input and output a decoded message 116. Various aspects of the memory system 100 may be controlled by the memory controller 104. In some implementations, the divide and conquer encoder 102 and the decoder 114 may be performed by the same component, process, or module.

In some examples of operation, the message 108 may be received from a central processing unit (not shown) or other processor or other component. The divide and conquer encoder 102 may encode the message 108 into the codeword 110 for storage in the memory 106. When read from the memory 106, the codeword 110 may be measured as the memory sensing result 112. The decoder 114 may decode the memory sensing result 112 to generate the decoded message 116. As explained in more detail below, the divide and conquer encoder 102 may use encoding technologies based on 2-lift based LDPC codes. The following figures and accompanying description provide further explanation as to how an encoding problem represented by a Tanner graph may be divided into constituent sub-graphs to encode one or more bits of information.

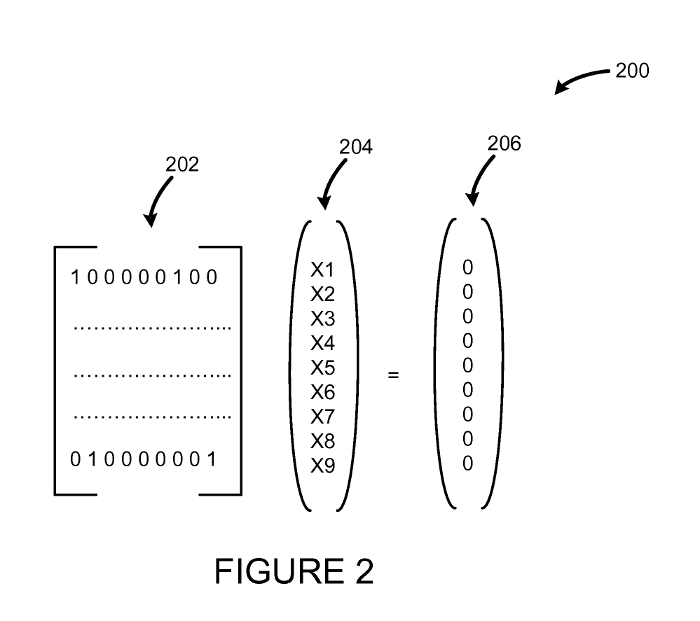

FIG. 2 illustrates an example of a parity check equation 200 that may be used as a basis for 2-lift based LDPC encoding, arranged according to at least some embodiments presented herein. The parity check equation 200 may be represented by a parity check matrix 202, a vector 204 of binary variables representing a codeword, and an all-zero vector 206. The parity check matrix 202 may be a sparse matrix. As used herein, a sparse matrix may be a matrix in which most elements of the matrix are zeroes.

As represented herein, the parity check equation 200 may be satisfied if the multiplication of the parity check matrix 202 and the vector 204 equals the all-zero vector 206. It is noted that, as described herein, multiplication and addition rules may be binary, unless indicated otherwise. For the purposes of addition, the following rules may apply: 0+0=0, 0+1=1, 1+0=1, and 1+1=0. For the purposes of multiplication, the following rules may apply: 0×0=0, 0×1=0, 1×0=0, and 1×1=1.

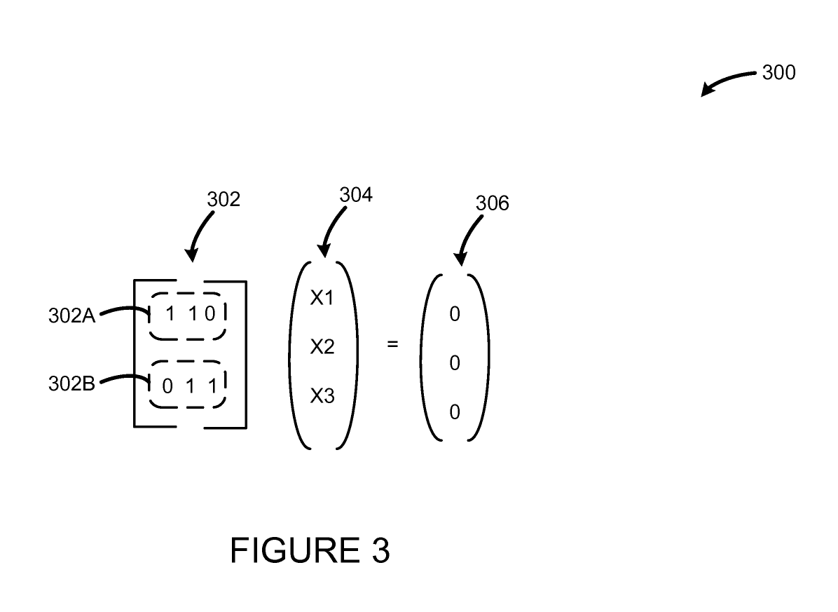

FIG. 3 is an illustration providing an example of a parity check equation 300 having numerical values, arranged according to at least some embodiments presented herein. A parity check matrix 302 may include two rows and three columns. There may exist multiple ways of encoding the message into the codewords. In some techniques, the encoding may be performed in a systematic manner. For example, the bits of the message to be transmitted may be exactly equal to some xN in the codeword. For example, in FIG. 3, the codeword 304 may be designed such that a message bit may be always equal to x1.

The parity check matrix 302 may be represented using a Tanner graph. A Tanner graph may be a bipartite graph. The nodes of the Tanner graph may be divided into two parts or partitions. The first part of a Tanner graph may be comprised of all variable nodes. In some implementations, a variable node may represent one variable xN. The other part of the Tanner graph might be comprised of all check nodes. In some examples, a check node may represent one parity check, or one row of the parity check matrix. There may exist one edge between one variable node and one check node, if and only if, the variable xN gets involved in the parity check or row of the parity check matrix.

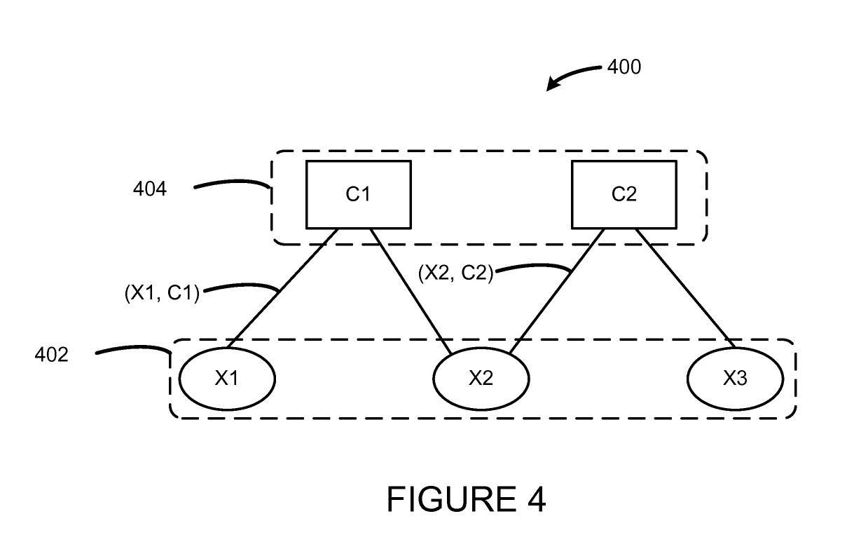

FIG. 4 is an example of a Tanner graph 400 representation of the parity check equation 300 in FIG. 3, arranged according to at least some embodiments presented herein. As illustrated, the graph 400 may contain two parts. The first part may include variable nodes 402, individually identified as variable nodes X1, X2, and X3. The second part may include check nodes 404, individually identified as check nodes C1 and C2. As illustrated, the check node C1 has couplings to variable node X1 and X2, the relationship of which may represent the condition that the sum of variables X1 and X2 are zero. The condition that the sum of the variables X1 and X2 is zero may be the linear constraint identified in row 302A of the parity check matrix 302 of FIG. 3. The check node C2 has couplings to variable nodes X2 and X3. This relationship may represent the condition that the sum of variables X2 and X3 are zero. The condition that the sum of the variables X2 and X3 are zero may also be the linear constraint identified by the row 302B of the parity check matrix 302 in FIG. 3.

In some examples, parity check matrices may have several thousand rows and columns due to the size of data to be encoded. Because of the relatively large number of rows and columns, encoding processes using LPDC codes may be configured to solve large parity check equations. To reduce the relative size of the encoding problems, various examples of the presently disclosed subject matter characterize an encoding problem into 2-lift based LPDC codes.

A graph lifting may be a process of generating a bigger graph from a smaller graph. The graph lifting process may include the following operations. In the first operation, “K” copies of an original smaller graph, or the “base graph,” may be generated, where K is a positive integer. For a variable (check) node in a base graph, there may be K copies of the variable (check) node in the generated graph. The K copies of the variable (check) node may be called the “fiber” of the variable (check) node in the base graph. In a second operation of a graph lifting process, the edges in the generated graphs may be permuted in a constrained way.

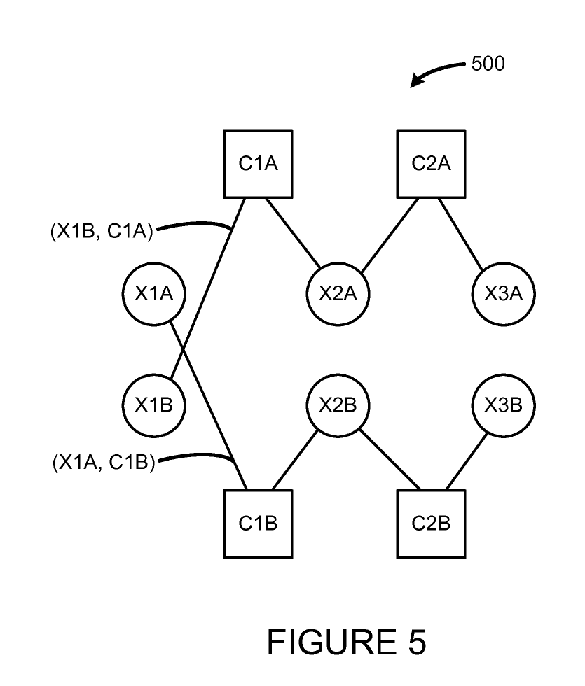

For example, the Tanner graph in FIG. 5 is an example of a 2-lift of the Tanner graph in FIG. 4. In FIG. 5, X1A and X1B are two variable nodes in one fiber and C1A, C1B are two check nodes in one fiber of the Tanner graph. After the first operation in the graph lift, there may be an edge (X1A, C1A) between X1A and C1A and an edge (X1B, C1B) between X1B and C1B. When performing the second operation of one 2-lift of the Tanner graph 400 in FIG. 4, an edge permutation may remove the edges (X1A, C1A) and (X1B, C1B) and add the edge (X1A, C1B) between X1A and C1B, and the edge (X1B, C1A) between X1B, and C1A. In some implementations, an edge permutation may be called a basic edge permutation. The edge permutation in the second operation may be comprised of several basic edge permutations. The resulting bigger graph is called a K-lift of the base graph, illustrated in more detail by way of example in FIG. 5.

In the example Tanner graph 500 of FIG. 5, the edge permutations to perform a 2-lift of the Tanner graph 400 of FIG. 4 may result in an edge (X1A, C1B) and an edge (X1B, C1A). Other edge permutations may be performed. A 2-lift may be performed on the Tanner graph 500 in a manner similar to the 2-lift operation performed on the Tanner graph 400 of FIG. 4. Thus, there may exist multiple K-lifts for a base graph. Using 2-lift based LPDC codes from a base graph G(0), a sequence of graphs G(1), G(2), . . . , G(K) may be generated, where each graph G(k) may be a 2-lift of the smaller graph G(k−1).

The process of lifting based graphs may be performed in the reverse, wherein a Tanner graph may be deconstructed into smaller graphs. For example, the Tanner graph 500 of FIG. 5 may be divided into the Tanner graph 400 of FIG. 4. In various implementations of the presently disclosed subject matter, an encoding problem on a G(k) Tanner graph can be decomposed (divided) into two encoding problems on a smaller G(k−1) Tanner graph. In other implementations, an encoding problem on a G(k−1) Tanner graph may be further decomposed into two encoding problems on a smaller G(k−2) Tanner graph. The encoding problem may be decomposed into smaller encoding problems as appropriate. Once decomposed, the data to be transmitted and encoded may be encoded using smaller parity check matrices formed by the decomposition of larger parity check matrices.

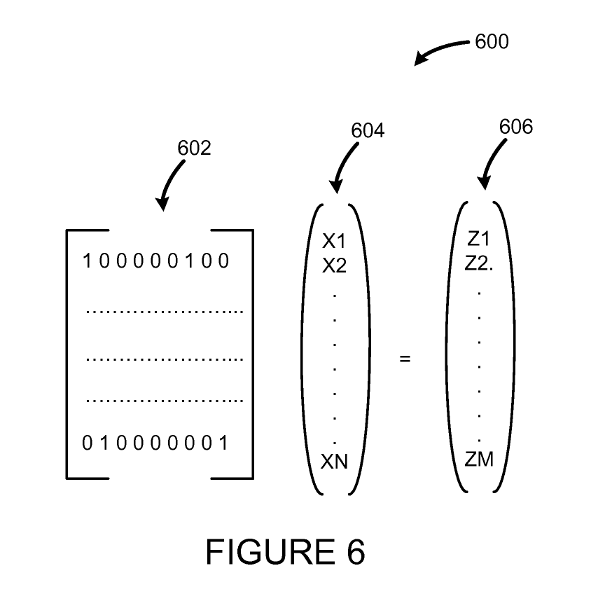

FIG. 6 is an illustration providing an example of a parity check equation 600 that may be solved by decomposing the parity check equation 600 into smaller encoding problems, arranged according to at least some embodiments presented herein. The parity check equation 600 may be represented by parity check matrix 602, a vector 604, and a vector 606. The vector 604 may be a codeword on a corresponding Tanner graph (G) if the vector 606 is an all zero vector and the equation 600 in FIG. 6 is satisfied. The vector 604 may be a “generalized” codeword on a corresponding Tanner graph (G) with respect to a vector 606 if the equation 600 in FIG. 6 is satisfied.

A covered generalized codeword “U” on a base graph G(k−1) of a 2-lift graph G(k) with respect to the generalized codeword 604 may be represented in the following manner. For each bit U(n) in the vector U, if X(na) and X(nb) are the two bits corresponding to the two variable nodes in the fiber of the variable corresponding to the bit U(n), then U(n) may be the sum of X(na) and X(nb). For each bit V(n) in the parity check vector V on the base graph G(k−1) of a 2-lift graph G(k) with respect to the parity check vector 606, if Z(na) and Z(nb) are the two bits corresponding to the two check nodes in the fiber of the check corresponding to the bit V(n), then V(n) may be the sum of Z(na) and Z(nb). Thus, the above vector U may be a generalized codeword on a Tanner graph G(k−1) with respect to the parity check vector V. The following is an example of an implementation.

Consider the 2-lift graph G(1) in FIG. 5. The graph G(1) is a 2-lift graph of the base graph G(0) in FIG. 4. Consider a generalized codeword X with:

X1a=1,

X2a=0,

X3a=1,

X1b=1,

X2b=1, and

X3b=1.

A corresponding parity check Z has:

C1a=1,

C2a=1,

C1b=0, and

C2b=0.

A covered codeword U on the base graph G(0) is:

U(1)=X(1)=X1a+X1b=0,

U(2)=X(2)=X2a+X2b=1, and

U(3)=X(3)=X3a+X3b=0

Thus, a corresponding parity check V has:

V(1)=Z(c1)=c1a+c1b=1 and

V(2)=Z(c2)=c2a+c2b=1.

Returning to FIG. 6, some bits in the vector 604 may be set according to data to be stored in a memory. The encoding process may include calculating the other bits in the vector 604 such that the vector 604 is a generalized codeword with respect to the all zero vector 606. In some implementations of the presently disclosed subject matter, the following techniques may be used to choose the systematic bits (these bits that are equal to the transmit information bits). A subset of the variable nodes on a Tanner graph may be initially selected to contain the systematic bits. The subset may be identified as the fibers of the variable nodes in a chosen subset on a base graph.

In some implementations, it may be more efficient to solve a generalized problem with the LDPC encoding problem as a special case. A formulation of a generalized problem may be as follows. A sequence of 2-lift graphs is provided: G(0), G(1), . . . , G(K), where each G(k) may be a 2-lift of G(k−1), G(0) may be a protograph, and G(K) is the final Tanner graph of the LDPC code. As used herein, a protograph based LDPC code may be an LDPC code with a graph lift as the Tanner graph. A set “S” of variable nodes in the protograph G(0) may be chosen such that each variable node in the final Tanner graph G(K) in at least one fiber of one variables node in S is set to a certain storage information bit. For instance, the values of these variable nodes may be known. Given the parity check vector Z on the final Tanner graph G(K), the problem may include solving for a vector X such that the vector X is a generalized codeword on the final Tanner graph G(K) with respect to the parity check vector Z.

In some implementations, a divide-and-conquer approach may be used to solve the above encoding problem. A divide-and-conquer approach for the above problem on the Tanner graph G(K) may be performed by reducing to two smaller size problems on G(K−1). Problems on larger size graphs might be reduced to problems on the protograph G(0). In some configurations, problems on a protograph G(0) may be solved by using a matrix inverse. Because of the relatively small size of the problems on the protograph G(0), the matrix inverse methods can have relatively low computational complexities.

The following is an example of how an encoding problem on a graph G(k) may be decomposed into two problems on a relatively smaller graph G(k−1). For the purposes of describing the present example, certain terminology may be used. The variable nodes on the graph G(k−1) can be referred to as X(1), X(2), . . . , X(N), and the check nodes on the graph G(k−1) can be referred to as Z(1), Z(2), . . . , Z(M). The variable nodes on the graph G(k) may be divided into two sets: X(1a), X(2a), . . . , X(Na), and X(1b), X(2b), . . . , X(Nb). The variable nodes may be divided in a manner so that X(na) and X(nb) are two variables node in the fiber of the variable node X(n) in the G(k−1) graph. Similarly, the check nodes on the graph G(k) may also be divided into two sets: Z(1a), Z(2a), . . . , Z(Ma), and Z(1b), Z(2b), . . . , Z(Mb), such that Z(ma) and Z(mb) are the two check nodes in the fiber of the check node Z(m) on the G(k−1) graph. It should be noted that the check nodes in the present example are designated as “Z,” whereas the check nodes in previous examples are designated as “C.” The difference in designation is merely for purposes of illustration.

Continuing with the present example, the variable nodes X(1a), X(2a), . . . , X(Na) and check nodes Z(1a), Z(2a), . . . , Z(Ma) may be considered as the first copy of the base graph in a 2-lifting operation. For each u-th edge of each m-th check node Z(ma) in the first copy of the graph lifting, a crossing parameter Y(mau) may be provided. For instance, Y(mau)=1 if the u-th edge is between two nodes from two different copies in the graph lifting, and Y(mau)=0, if the u-th edge is not between two nodes from two different copies in the graph lifting.

A modified parity check Q(ma) may be provided, where m=1, 2, . . . , M. Assume that the check node Z(ma) has U edges. The variable node incident to the u-th edge may be denoted by Xp(mu). The covered variable node of Xp(mu) in the base graph G(k−1) may be denoted by Xq(mu). In other words, Xp(mu) is in the fiber of Xq(mu). Q(ma) may be provided as Q(ma)=Z(ma)+Xq(m1)Y(ma1)+ . . . +Xq(mu)Y(mau)+ . . . +Xq(mU)Y(maU). Lemma 2: The vector X(1), X(2), . . . , X(N) may be a generalized codeword with respect to the parity check vector Z(1), Z(2), . . . , Z(M) on the first copy of the base graph G(k−1) in the 2-lift process, where X(1)=X(1a), X(2)=X(2a), . . . , X(N)=X(Na), Z(1)=Q(1a), Z(2)=Q(2a), . . . , Z(M)=Q(Ma).

If the crossing parameter Y(mau) is 1, then the corresponding edge may be coupled to one variable Xp(mu) in the other graph copy. A basic edge permutation may be used so that the edge may be coupled to the variable node Xr(mu) instead, where Xp(mu) and Xr(mu) are in the same fiber. If the covered variable Xq(mu) is 1, then Xp(mu) and Xr(mu) may have different values. Therefore, the corresponding check of the edge should change value one time after the basic edge permutation. Thus, a sequence of basic edge permutations may be used so that, in the resulting Tanner graph, there is no edge that couples the two copies of the base graphs. The first copy of the graph may be identical to the base graph after all these basic edge permutations. In some configurations, the values of the checks during the edge permutations can be traced. Further, in some examples, if the covered variable node value is 1, then the two variable nodes in fiber may have different values. In the graph without the edge permutation, the parity check may change its value once.

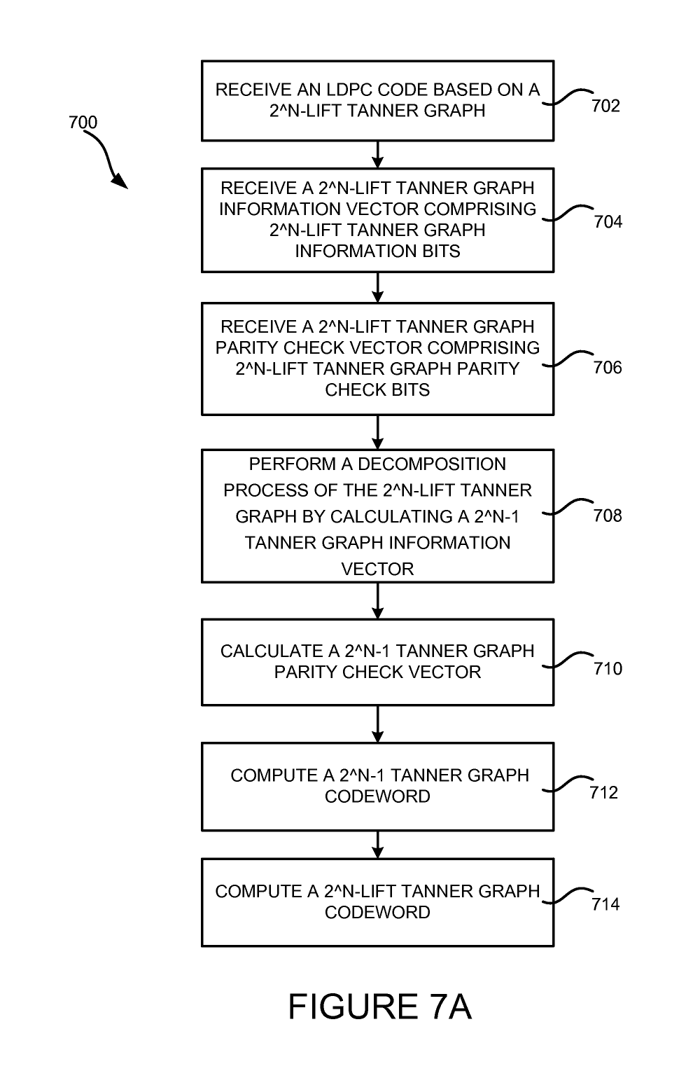

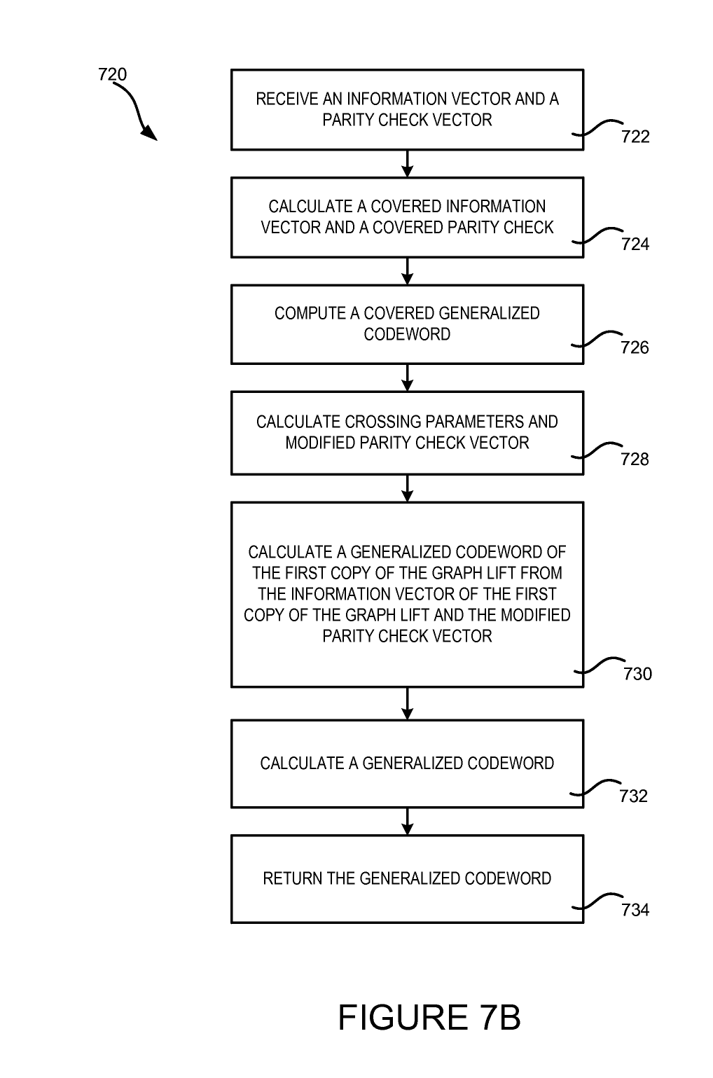

FIG. 7A is a flow diagram of an example encoding process 700, arranged according to at least some embodiments presented herein. The operations of any process described herein are not necessarily presented in any particular order and performance of some or all of the operations in an alternative order(s) is possible and is contemplated. The operations have been presented in the demonstrated order for ease of description and illustration. Operations may be added, combined, modified, supplemented, omitted, and/or performed simultaneously, in a different order, etc., without departing from the scope of the present disclosure.

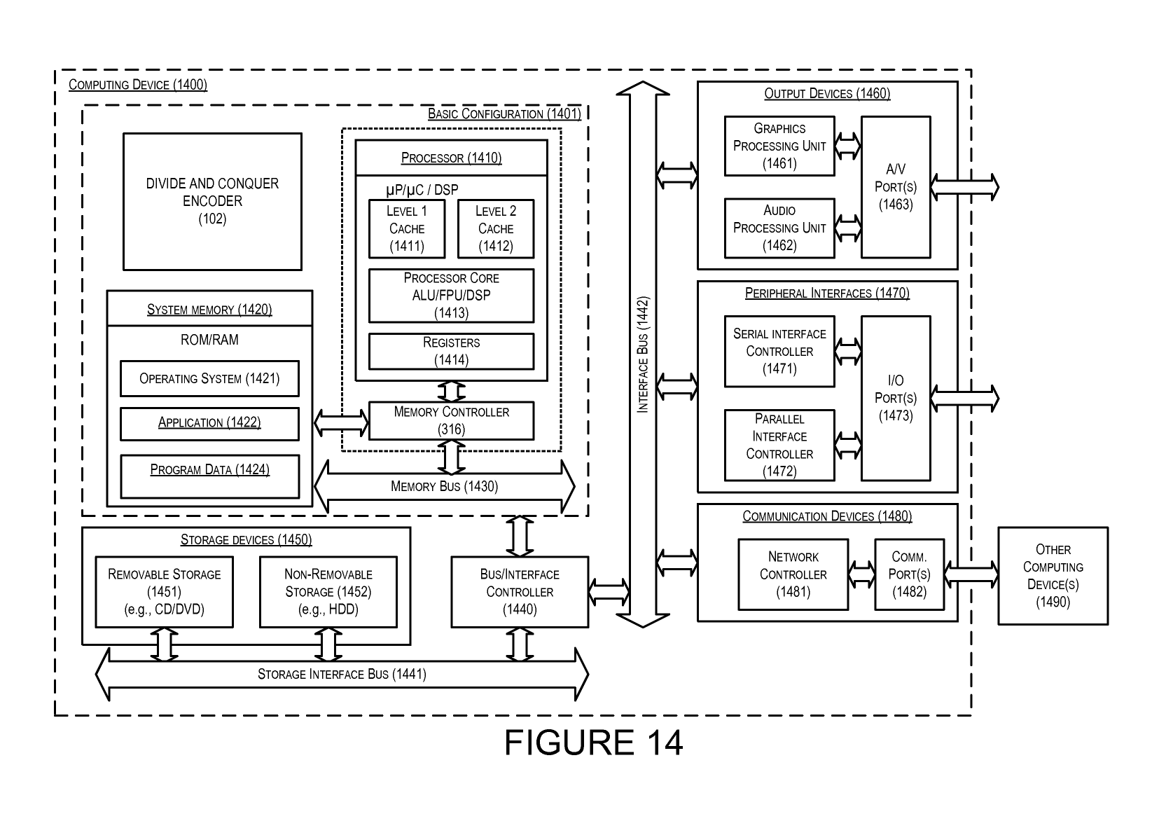

The illustrated processes can be ended at any time and need not be performed in its entirety. Some or all operations of the processes, and/or substantially equivalent operations, can be performed in one embodiment by execution (by one or more processors) of computer-readable instructions included on a computer storage media, as disclosed herein, including a tangible non-transitory computer-readable storage medium. The term “computer-readable instructions,” and variants thereof, as used in the description and claims, is used expansively herein to include routines, applications, application modules, program modules, programs, components, data structures, algorithms, or the like. Computer-readable instructions can be implemented on various system configurations, including single-processor or multiprocessor systems, minicomputers, mainframe computers, personal computers, hand-held computing devices, microprocessor-based, programmable consumer electronics, combinations thereof, or the like. For purposes of illustrating and describing at least one embodiment of the present disclosure, the process 700 is described as being performed, at least in part, by the divide and conquer encoder 102 and/or some other divide and conquer unit or other component(s) described herein (which in turn may operate in conjunction with a processor, such as the processor 1410 of FIG. 14). This embodiment is illustrative, and the process 700, or other processed illustrated herein, may be performed in other ways.

The process 700 may begin at block 702 (“receive an LDPC code based on a 2̂n-lift Tanner graph”), where an LDPC code based on a 2̂n-lift Tanner graph is received. The lift (“n”) of the Tanner graph may vary, the presently disclosed subject matter not being limited to any particular lift. In some implementations, the lift may increase the complexity of the encoding and decoding process. In some implementations, the 2̂n-lift Tanner graph may be constructed from a 2̂n−1 Tanner graph by incorporating a first copy of the 2̂n−1 base Tanner graph into the 2̂n-lift Tanner graph, incorporating a second copy of the 2̂n−1 base Tanner graph into the 2̂n-lift Tanner graph, and modifying a plurality of end points of at least one edge in the first copy or the second copy of the 2̂n−1 base Tanner graph. One or more edges may have a first end point in the first copy of the 2̂n−1 base Tanner graph and a second end point in the second copy of the 2̂n−1 base Tanner graph.

In some implementations, at least one parity check bit on the 2̂n−1 base Tanner graph of the 2̂n-lift Tanner graph may be set as a binary summation of one parity check bit at one check node on a first copy of the 2̂n−1 base Tanner graph and one parity check bit at one check node on a second copy of the 2̂n−1 base Tanner graph.

The process 700 may continue to block 704 (“receive a 2̂n-lift Tanner graph information vector comprising 2̂n-lift Tanner graph information bits”), where a 2̂n-lift Tanner graph information vector comprising 2̂n-lift Tanner graph information bits is received. In some implementations, the 2̂n-lift Tanner graph information vector may be a vector such as one sub-vector of the vector 204 of FIG. 2. In some implementations, calculating the 2̂n−1 Tanner graph information vector comprising 2̂n−1 Tanner graph information bits on the 2̂n−1 base Tanner graph of the 2̂n-lift Tanner graph using the information bits of the received information vector comprises setting at least one information bit on the 2̂n−1 base Tanner graph of the 2̂n-lift Tanner graph as the binary summation of one information bit at one variable node on the first copy of the 2̂n−1 base Tanner graph and one information bit at one variable node on the second copy of the 2̂n−1 base Tanner graph.

The process 700 may continue to block 706 (“receive a 2̂n-lift Tanner graph parity check vector comprising 2̂n-lift Tanner graph parity check bits”), where a 2̂n-lift Tanner graph parity check vector comprising 2̂n-lift Tanner graph parity check bits is received. In some implementations, the 2̂n-lift Tanner graph parity check vector may be a vector such as the vector 606 of FIG. 6. In some implementations, the 2̂n-lift Tanner graph parity check vector may be an all-zero vector.

The process 700 may continue to block 708 (“perform a decomposition process of the 2̂n-lift Tanner graph by calculating a 2̂n−1 Tanner graph information vector”), where a decomposition process may be performed by calculating a 2̂n−1 Tanner graph information vector comprising 2̂n−1 Tanner graph information bits on a 2̂n−1 Tanner graph of the 2̂n-lift Tanner graph using the 2̂n-lift Tanner graph information bits of the 2̂n-lift Tanner graph information vector.

The process 700 may continue to block 710 (“calculate a 2̂n−1 Tanner graph parity check vector”), where the decomposition process is continued by calculating a 2̂n−1 Tanner graph parity check vector comprising 2̂n−1 Tanner graph parity check bits on the 2̂n−1 Tanner graph of the 2̂n-lift Tanner graph using the 2̂n-lift Tanner graph parity check bits of the 2̂n-lift Tanner graph parity check vector.

The process 700 may continue to block 712 (“compute a 2̂n−1 Tanner graph codeword”), where the decomposition process is continued by computing a 2̂n−1 Tanner graph codeword comprising 2̂n−1 Tanner graph codeword bits on the 2̂n−1 Tanner graph of the 2̂n-lift Tanner graph using the 2̂n−1 Tanner graph information vector and the 2̂n−1 Tanner graph parity check vector.

The process 700 may continue to block 714 (“compute a 2̂n-lift Tanner graph codeword”), where a 2̂n-lift Tanner graph codeword comprising 2̂n-lift Tanner graph codeword bits on the 2̂n-lift Tanner graph is computed using a 2̂n-lift graph edge configuration, the 2̂n−1 Tanner graph codeword, the 2̂n-lift Tanner graph information vector, and the 2̂n-lift Tanner graph parity check vector.

The process 700 may also include calculating a parity check vector comprising parity check bits on the first copy of the 2̂n−1 base Tanner graph using a 2̂n-lift Tanner graph edge configuration, the computed codeword on the 2̂n−1 base Tanner graph of the 2̂n-lift Tanner graph, and the received 2̂n-lift Tanner graph parity check vector.

The process 700 may additional include computing a codeword vector comprising codeword bits on the first copy of the 2̂n−1 base Tanner graph using a calculated parity check vector on the first copy of the 2̂n−1 base Tanner graph and the received information bits at the variable nodes on the first copy of the 2̂n−1 base Tanner graph.

The process 700 may further include computing a codeword vector comprising codeword bits for the second copy of the 2̂n−1 base Tanner graph using calculated codeword vector on the 2̂n−1 base Tanner graph of the 2̂n-lift Tanner graph and the codeword vector on the first copy of the 2̂n−1 base Tanner graph.

The process 700 may also include computing the codeword on the 2̂n-lift Tanner graph using the codeword vector on the first copy of 2̂n−1 base Tanner graph and the codeword vector on the second copy of the 2̂n−1 base Tanner graph.

In some implementations, the codeword bits may be equal to the received information bit at the variable node if the variable node receives only one information bit. In further implementations, the computed codeword on the first copy of the 2̂n−1 base Tanner graph and the received parity check bits on the first copy of the 2̂n−1 base Tanner graph may satisfy all the parity check constraints on the first copy of the 2̂n−1 base Tanner graph. In further implementations, the 2̂n-lift Tanner graph information vector may comprise at most one information bit for each variable node in the 2̂n-lift Tanner graph. The 2̂n-lift Tanner graph parity check vector can include one parity check bit for each check node in the 2̂n-lift Tanner graph. In some configurations, computing one codeword bit for each variable node in the 2̂n-lift Tanner graph and the computed codeword bit for each variable node may be equal to the received information bit, if the variable node receives exactly one information bit.

FIG. 7B is a flow diagram of another example encoding process 720 arranged according to at least some embodiments presented herein. The process 720 may begin at block 722 (“receive an information vector and a parity check vector”), where one generalized information vector and one generalized parity check vector may be received. Because some bits of the generalized codeword may be completely determined by the information to be stored (e.g., being systematic bits or corresponding to covered variable nodes of the systematic bits), their values may be known. The vector of these known values may be called the generalized information vector.

The process 720 may continue to block 724 (“calculate a covered information vector and a covered parity check”), where a covered information vector and a covered parity check vector may be calculated. The covered information vector may be the vector of the bits in the generalized codeword, such that the values of these bits may be determined by the transmit message.

The process 720 may continue to block 726 (“compute a covered generalized codeword”), where a covered generalized codeword may be calculated from the covered information vector and covered parity check vector on a base graph. In some examples, the process 720 may be repeated to further deconstruct the encoding problem into further, smaller encoding problems. In some examples, block 726 may be performed on base graphs having sufficiently small sizes.

The process 720 may continue to block 728 (“calculate crossing parameters and modified parity check vector”), where a modified parity check vector may be calculated according to the covered codeword and crossing parameters Y(ma).

The process 720 may continue to block 730 (“calculate a generalized codeword of the first copy of the graph lift from the information vector of the first copy of the graph lift and the modified parity check vector computed in the block 728”), where the generalized codeword of the first copy of the graph lift may be calculated from the information vector of the first copy of the graph lift and the modified parity check vector). Block 730 may recursively call the process 720, however with a different smaller-sized problem instance. Block 730 may also calculate the generalized codeword of the first copy of the graph lift using a brute force approach, for example in the cases that the base graphs have sufficiently small sizes.

The process 720 may continue to block 732 (“generate a generalized codeword”), where a generalized codeword may be computed based on the covered generalized codeword computed in block 726 and the generalized codeword of the first copy of the graph lift computed in block 730. The operation may continue to block 734 (“return the generalized codeword”), where the generalized codeword may be returned. The process may thereafter end.

The following is an example using the process 720. In this example, the LDPC code is represented by the Tanner graph in FIG. 5. The code may be a 2-lift based code, where the base graph is shown in FIG. 4. The Tanner graph in FIG. 5 has six variable nodes (X1A, X2A, X3A, X1B, X2B, and X3B) and four check nodes (C1A, C2A, C1B, and C2B). A corresponding parity check matrix may have 4 rows and 6 columns. Each codeword may have a length of 6 bits. In the present example, the information to be stored may be 2 bits per 6 bit block.

The variable nodes in the fiber of node X2 may be chosen as the information bits. Thus, the variable X2A and X2B may be equal to the message bits. The values of the four other variable nodes in the Tanner graph of FIG. 5 may be determined by the values of X2A, X2B and the four parity check constraints. In this example, at block 722, two information bits [01] may be received. For example, X2A=0, and X2B=1. A generalized parity check vector [0000] may also be received. For example, C1A=0, C2A=0, C1B=0, and C2B=0.

In block 724, a covered information vector may be calculated. The covered information vector in this example may have one dimension. The vector may be [X2]=[X2A+X2B]=1. The covered parity check vector may be [C1, C2], where C1=C1A+C1B=0, and C2=C2A+C2B=0. Therefore, the covered parity check vector may be [00].

In block 726, the covered generalized codeword may be computed. Note that the computation may be on the small graph in FIG. 4, where C1=0, C2=0, and X2=1. Because the graph has a small size, the parity check equations may be solved using a brute force approach. The covered generalized codeword may be [111]. For example, X1=1, X2=1, and X3=1.

In block 728, a modified parity check vector may be computed on the graph in FIG. 5. In this example, the variable and check nodes in the first copy in the graph lifting may be considered. Therefore, the variable nodes X1A, X2A, X3A and check nodes C1A, and C2A may be the nodes to be considered. The modified parity check vector may be [Q(1a) Q(2a)]. The Q(1a) may be computed based on C1A, the covered generalized codeword bits X1, and X2, and the crossing parameters Y(1A1) and Y(1A2). From the previous blocks, X1=1, X2=1, and C1A=0. The crossing parameter according to the examples may be Y(1A1)=1, because the first edge may be coupled to a variable node in the second copy in the graph lifting and Y(1A2)=0, because the second edge may be coupled to the variable node in the first copy in the graph lifting. Therefore, Q(1A)=1. Similarly, Q(2A)=0.

In the block 730, a generalized codeword may be computed on the first copy of the base graph, where the generalized information bits may be equal to the generalized information bits in the first copy in the graph lifting. In this example, the parity check vector may be equal to the modified parity check vector computed in the block 728. According to the example, the information bit X2=0 and the modified parity check vector may be [10], for instance C1=1, C2=0. Using a brute force approach, it may be determined that X1=1, X2=0, X3=0. Mapping back to the first copy in the graph lifting, it may be determined that X1A=1, X2A=0, X3A=0.

In the block 732, it may be known that X1=1, X2=1, X3=1, X1A=1, X2A=0, and X3A=0. Because X1=X1A+X1B, X2=X2A+X2B, X3=X3A+X3B, we have X1B=0, X2B=1, X3B=1. The generalized codeword has been computed. In the block 734, the generalized codeword may be returned.

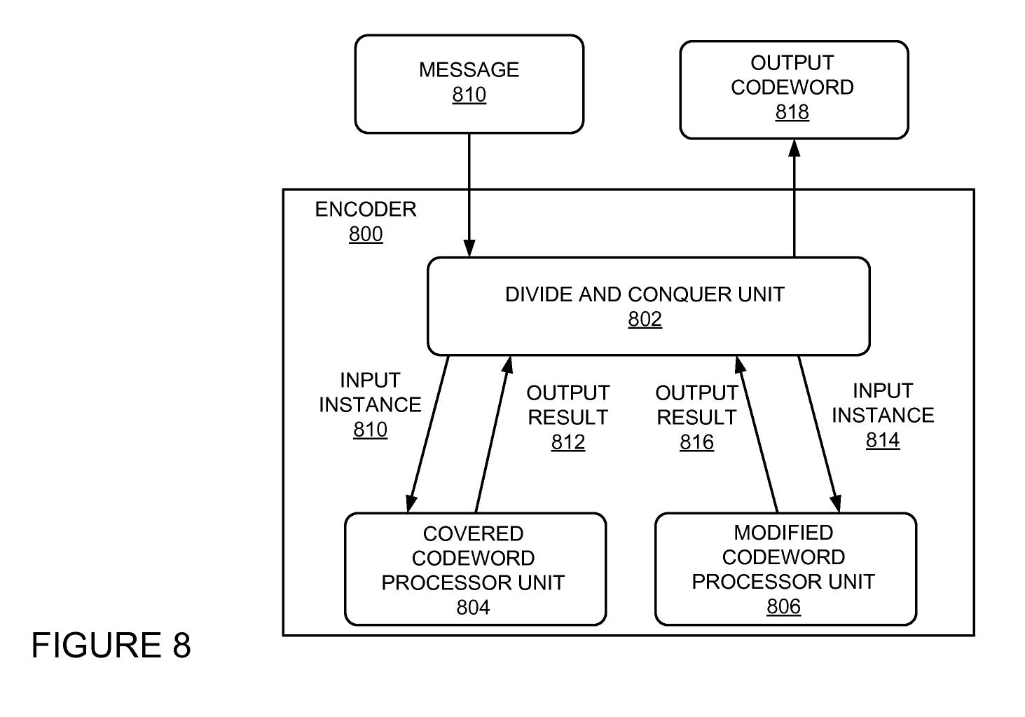

FIG. 8 is a block diagram illustrating an example encoder 800, arranged according to at least some embodiments presented herein. The encoder 800 may comprise a divide and conquer unit 802, a covered codeword processor unit 804, and a modified codeword processor unit 806, which may all be operatively coupled to each other. If a message 810 is received by the encoder 800, the message 810 may be passed to the divide and conquer unit 802.

The divide and conquer unit 802 may generate a smaller sized problem instance 810 and pass the instance 810 to the covered codeword processor unit 804 as an input. The covered codeword processor unit 804 may receive the smaller sized problem instance 810 and generate a solution output result 812. The covered codeword processor unit 804 may return the solution output result 812 to the divide and conquer unit 802.

Based on the instance 810 and the output result 812, the divide and conquer unit 802 may generate a smaller sized problem instance 814. The divide and conquer unit 804 may pass the problem instance 814 to the modified codeword processor unit 806 as an input. The modified codeword processor unit 806 may receive the problem instance 814, and generate a solution, as an output result 816. The modified codeword processor unit 806 may return the output result 816 to the divide and conquer unit 802. The divide and conquer unit 802 may then compute an output codeword 818 based on the received output result 812 and output result 816. The output codeword 818 may be the LDPC codeword to be computed.

One consideration of some hardware implementations of LDPC decoding is how to route the messages. Routing congestion and memory conflicting may occur. Various aspect of the presently disclosed subject matter may provide a method for implementing the protograph based LDPC code decoding in hardware, where certain message exchanging paths may be grouped and mapped into block memory elements. Some implementations of the presently disclosed subject matter may thus address the routing congestion and memory conflicting considerations.

The Tanner graph in FIG. 5 may be a relatively simple example of a Tanner graph. In application in some computing systems, the Tanner graphs may have several thousands of variable nodes and check nodes. Routing all the messages from variable nodes to check nodes and from check nodes to variable nodes may be more complex. In some situations, there may exist routing congestions and memory conflicts. In some examples, memory conflicts may be resolved, or the probability of memory conflicts reduced, if the message passing is either all from the variable nodes to the check nodes, or all from the check nodes to variable nodes. When variable node units need the memory blocks for message passing, check node units may not pass any message, and verse versa. The term “variable node unit” may be used herein to refer to one or more circuits, code or devices operable to generate variable node to check node messages. The terms “check node unit” may be used herein to refer to one or more circuits, code or devices operable to generate check node to variable node messages.

One or more of the variable node units may correspond to a variable node in a protograph, or the variable nodes in the fiber of the variable node in the protograph. Some of the message calculations at these variable nodes in the fiber may be carried out by a variable node unit. In some examples, a check node unit may correspond to one check node in a protograph, or the check nodes in the fiber of the check node in the protograph. The message calculations at these check nodes in the fiber may be carried out by the check node unit. The memory block may correspond to one edge in a protograph. The memory block may have one coupling (e.g., a bus) to a variable node unit corresponding to one end of the edge in a protograph. The memory block may have another coupling (e.g., a bus) to a check node unit corresponding to the other end of the edge in a protograph. That is, each memory block may have one coupling to one variable node unit and one check node unit. The variable node unit and check node unit may exchange messages using the memory block.

In some implementations, a memory block may comprise a dual-port memory block. The memory block may also be wrapped by some multiplexer logic circuits, such that the variable node unit and check node unit may both access the memory block (at different time intervals). The messages in iterative decoding can be routed to the destinations using the memory blocks between the variable node units and check node units. There may be no (or otherwise reduced) memory conflicting, because at each time interval, message passing may be either all from variable nodes to check nodes, or all from check nodes to variable nodes. In other words, when the variable node units need the memory blocks for message-passing, the check node units do not need to pass any message, and verse versa.

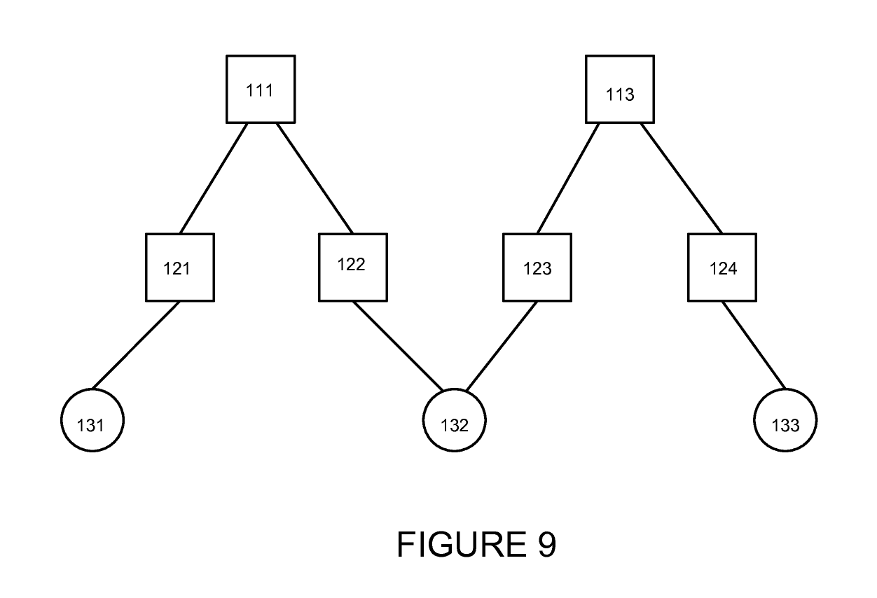

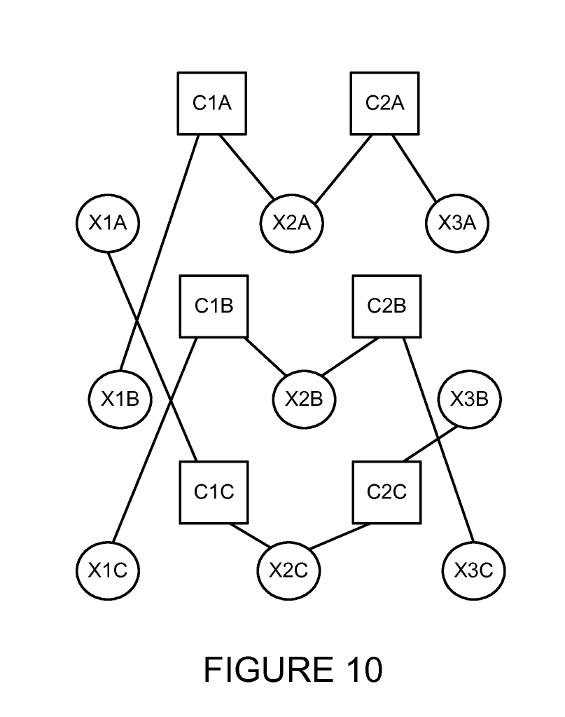

FIG. 9 is an illustration of an example of a hardware implementation to perform a method for LDPC decoding, arranged according to at least some embodiments presented herein. The LDPC code in the example illustrated in FIG. 9 may have an example Tanner graph representation illustrated in FIG. 10. The LDPC code may be a protograph based LDPC code with the protograph being illustrated in FIG. 4.

The hardware implementation of FIG. 9 may include circuits that comprise two check node units 111, 113, three variable node units 131, 132, 133, and four memory blocks 121, 122, 123, 124 operatively coupled to each other. The check node unit 111 may carry out the message calculations at check nodes C1A, C1B, and C1C of FIG. 10. The check node unit 113 may carry out the message calculations at check nodes C2A, C2B, and C2C of FIG. 10. The variable node unit 131 may carry out the message calculations at variable nodes X1A, X1B, and X1C of FIG. 10. The variable node unit 132 may carry out the message calculations at variable nodes X2A, X2B, and X2C of FIG. 10. The variable node unit 133 may carry out the message calculations at variable nodes X3A, X3B, and X3C of FIG. 10.

The messages may be passed between variable node units and check node units by using memory blocks 121, 122, 123 and 124. These memory blocks 121, 122, 123 and 124 may comprise dual-port memories. For example, in the operation of passing messages from variable node units 131, 132, 133 to check node units 111, 113, the variable node units 131, 132, 133 may write the messages into the memory blocks 121, 122, 123 and 124. The check node units 111, 113 may then read these messages from the memory blocks 121, 122, 123 and 124.

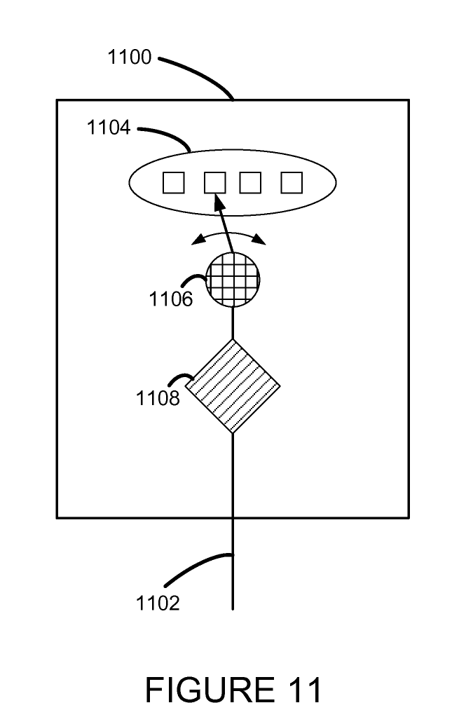

FIG. 11 is an illustration of a check node unit 1100, arranged according to at least some embodiments presented herein. In FIG. 11, an input/output (I/O) bus 1102 may couple the check node unit 1100 to one of the memory blocks arranged according to at least some embodiments presented herein. The check node unit 1100 may carry out message computing tasks for one fiber of check nodes 1104. A selector 1106 may be used to select the next to-be-processed check operation during a particular time interval. During each time interval, a processor 1108 coupled to the selector 1106 may first examine one check node in the fiber of check nodes 1104 and its edge couplings. The processor 1108 may then read a message from a memory block, such as the memory blocks 121, 122, 123 and 124 of FIG. 9, using the I/O bus 1102. The processor 1108 may calculate an output message for the check operation and send the output message to a particular memory block, such as one of the memory blocks 121, 122, 123 and 124 of FIG. 9.

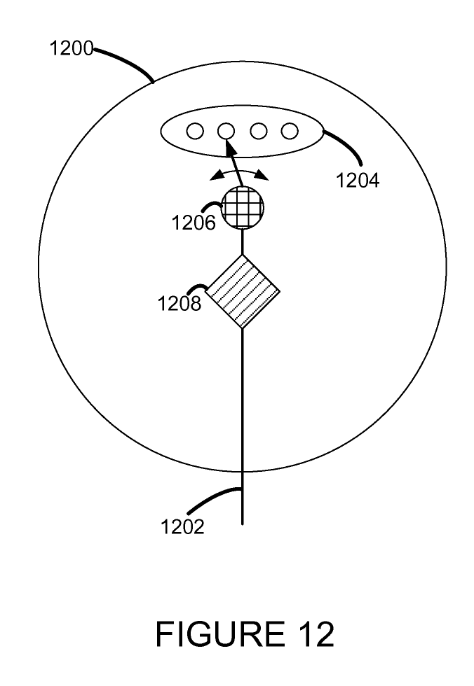

FIG. 12 is an example of a variable node unit 1200, arranged according to at least some embodiments presented herein. An I/O bus 1202 may couple the variable node unit 1200 to a memory block, such the memory blocks 121, 122, 123 and 124 of FIG. 9. The variable node unit 1200 may carry out a message computing task for one fiber of variable nodes 1204. A selector 1206 may be used to select the next to-be-processed variable node during a time interval. During a time interval, a processor 1208 coupled to the selector 1206 may first examine one variable node and its edge couplings. The processor 1208 may then read the messages from a memory block using the I/O bus 1202. The processor 1208 may calculate output messages for the variable node and send these messages to a memory block, such as one of the memory blocks 121, 122, 123 and 124 of FIG. 9.

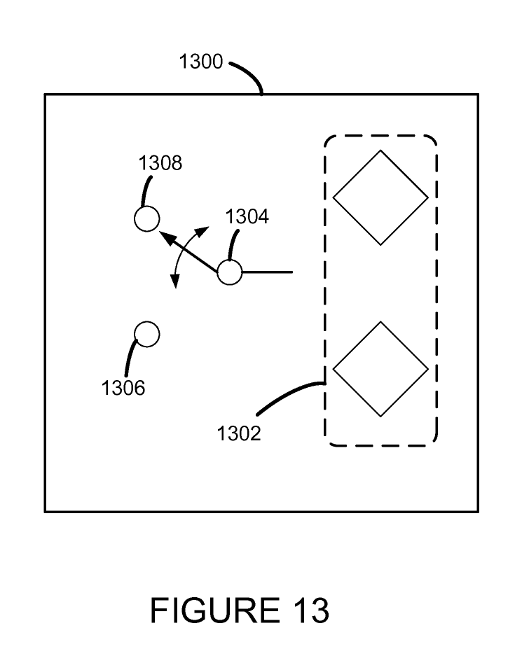

FIG. 13 is an illustration of an example of a memory block 1300, arranged according to at least some embodiments presented herein. The memory block 1300 may comprise a memory 1302, a multiplexer 1304, a bus to variable node 1306, and bus to check node 1308 operatively coupled to each other. In some implementations, in each operation of message-passing algorithms, the messages may be either passing from all variable nodes to all check nodes, or from all check nodes to all variable nodes. If the messages are to be passed from variable nodes to check nodes, the multiplexer 1304 may be first set such that a variable node unit, such as the variable node unit 1200 of FIG. 12, may write certain messages using the bus 1306. The multiplexer 1304 may then be set, such that a check node unit may read the passed messages using the bus 1308. Similarly, if the messages need to be passed from check nodes to variable nodes, the multiplexer 1304 may be first set such that a check node unit may write certain messages using the bus 1308. The multiplexer 1304 may then be set such that a variable node unit may read the passed messages using the bus 1306.

FIG. 14 is a block diagram illustrating an example computing device 1400 that is arranged to implement various aspects of the presently disclosed subject matter, including implementation for an LDPC encoder for 2-lift based LDPC codes arranged in accordance with at least some embodiments described herein. In a very basic configuration, computing device 1400 includes one or more processors 1410 and system memory 1420. A memory bus 1430 can be used for communicating between the processor 1410 and the system memory 1420.

Depending on the desired configuration, the processor 1410 can be of any type including but not limited to a microprocessor (“μP”), a microcontroller (“μC”), a digital signal processor (“DSP”), or any combination thereof. Processor 1410 (which can be used to implement the processor 1108 and/or other processor described above) can include one more levels of caching, such as a level one cache 1411 and a level two cache 1412, a processor core 1413, and registers 1414. The processor core 1413 can include an arithmetic logic unit (“ALU”), a floating point unit (“FPU”), a digital signal processing core (“DSP core”), or any combination thereof. A memory controller 316 (which can be used to implement the memory controller 104) can also be used with the processor 1410, or in some implementations the memory controller 316 can be an internal part of the processor 1410.

Depending on the desired configuration, the system memory 1420 (which can be used to implement the memory 106) can be of any type including but not limited to volatile memory (such as RAM), non-volatile memory (such as ROM, flash memory, etc.) or any combination thereof. System memory 1420 typically includes an operating system 1421, one or more applications 1422, and program data 1424. Application 1422 can include instructions that allow the processor 1410 to use the memory controller 316 to access the system memory 1420. The system memory 1420 and/or other element(s) of the computing device 1400 can include components that can be used to implement the divide and conquer encoder 102 and the decoder 114 of FIG. 1, the encoder 800 of FIG. 8, as well as the variable node units and the check node units described in FIGS. 9-13. Program Data 1424 includes data that is usable in connection with implementing or operating the divide and conquer encoder 102 and/or other encoding/decoding components previously described above. This described basic configuration is illustrated in FIG. 14 by those components within dashed line 1401.

Computing device 1400 can have additional features or functionality, and additional interfaces to facilitate communications between the basic configuration 1401 and any required devices and interfaces. For example, a bus/interface controller 1440 can be used to facilitate communications between the basic configuration 1401 and one or more data storage devices 1450 via a storage interface bus 1441. The data storage devices 1450 can be removable storage devices 1451, non-removable storage devices 1452, or a combination thereof. Examples of removable storage and non-removable storage devices include magnetic disk devices such as flexible disk drives and hard-disk drives (“HDDs”), optical disk drives such as compact disk (“CD”) drives or digital versatile disk (“DVD”) drives, solid state drives (“SSDs”), and tape drives to name a few. Example computer storage media can include volatile and nonvolatile, removable and non-removable media implemented in any method or technology for storage of information, such as computer readable instructions, data structures, program modules, or other data.

System memory 1420, removable storage devices 1451 and non-removable storage devices 1452 are all examples of computer storage media. Computer storage media includes, but is not limited to, RAM, ROM, EEPROM, flash memory or other memory technology, CD-ROM, digital versatile disks (“DVDs”) or other optical storage, magnetic cassettes, magnetic tape, magnetic disk storage or other magnetic storage devices, or any other medium which can be used to store the desired information and which can be accessed by computing device 1400. Any such computer storage media can be part of device 1400.

Computing device 1400 can also include an interface bus 1442 for facilitating communication from various interface devices (e.g., output interfaces, peripheral interfaces, and communication interfaces) to the basic configuration 1401 via the bus/interface controller 1440. Example output devices 1460 include a graphics processing unit 1461 and an audio processing unit 1462, which can be configured to communicate to various external devices such as a display or speakers via one or more A/V ports 1463. Example peripheral interfaces 1470 include a serial interface controller 1471 or a parallel interface controller 1472, which can be configured to communicate with external devices such as input devices (e.g., keyboard, mouse, pen, voice input device, touch input device, etc.) or other peripheral devices (e.g., printer, scanner, etc.) via one or more I/O ports 1473.

An example communication device 1480 includes a network controller 1481, which can be arranged to facilitate communications with one or more other computing devices 1490 over a network communication via one or more communication ports 1482. The communication connection is one example of a communication media. Communication media may typically be embodied by computer readable instructions, data structures, program modules, or other data in a modulated data signal, such as a carrier wave or other transport mechanism, and includes any information delivery media. A “modulated data signal” can be a signal that has one or more of its characteristics set or changed in such a manner as to encode information in the signal. By way of example, communication media can include wired media such as a wired network or direct-wired connection, and wireless media such as acoustic, radio frequency (“RF”), infrared (“IR”) and other wireless media. The term computer readable media as used herein can include both storage media and communication media. Storage media does not encompass communication media.

Computing device 1400 can be implemented as a portion of a small-form factor portable (or mobile) electronic device such as a cell phone, a personal data assistant (“PDA”), a personal media player device, a wireless web-watch device, a personal headset device, an application specific device, or a hybrid device that include any of the above functions. Computing device 1400 can also be implemented as a personal computer including both laptop computer and non-laptop computer configurations.

The present disclosure is not to be limited in terms of the particular embodiments described in this application, which are intended as illustrations of various aspects. Many modifications and variations can be made without departing from its spirit and scope. Functionally equivalent methods and apparatuses within the scope of the disclosure, in addition to those enumerated herein, are possible. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, compounds, or compositions, which can, of course, vary. It is also to be understood that the terminology used herein is for the purpose of describing particular embodiments only, and is not intended to be limiting.

Other memory access technologies and techniques may be used and are still considered to be within the scope of the present disclosure. Additionally, for purposes of clarity, one or more components of the circuits in the figures may not be illustrated but may be included. The circuits illustrated are not limited to the components illustrated and may include more or fewer components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations.

However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include, but not be limited to, systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group. Further, the use of the terms “first,” “second,” “third,” “fourth,” and the like is to distinguish between repeated instances of a component or a step in a process and does not impose a serial or temporal limitation unless specifically stated to require such serial or temporal order.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” or the like include the number recited and refer to ranges which can be subsequently broken down into subranges as discussed above. Finally, as will be understood by one skilled in the art, a range includes each individual member. Thus, for example, a group having 1-3 elements refers to groups having 1, 2, or 3 elements. Similarly, a group having 1-5 elements refers to groups having 1, 2, 3, 4, or 5 elements, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A method to encode a message, the method comprising:
receiving an LDPC code based on a 2̂n-lift Tanner graph;
receiving a 2̂n-lift Tanner graph information vector comprising 2̂n-lift Tanner graph information bits;
receiving a 2̂n-lift Tanner graph parity check vector comprising 2̂n-lift Tanner graph parity check bits;
performing a decomposition process of the 2̂n-lift Tanner graph by:
calculating a 2̂n−1 Tanner graph information vector comprising 2̂n−1 Tanner graph information bits on a 2̂n−1 Tanner graph of the 2̂n-lift Tanner graph using the 2̂n-lift Tanner graph information bits of the 2̂n-lift Tanner graph information vector,
calculating a 2̂n−1 Tanner graph parity check vector comprising 2̂n−1 Tanner graph parity check bits on the 2̂n−1 Tanner graph of the 2̂n-lift Tanner graph using the 2̂n-lift Tanner graph parity check bits of the 2̂n-lift Tanner graph parity check vector, and
computing a 2̂n−1 Tanner graph codeword comprising 2̂n−1 Tanner graph codeword bits on the 2̂n−1 Tanner graph of the 2̂n-lift Tanner graph using the 2̂n−1 Tanner graph information vector and the 2̂n−1 Tanner graph parity check vector; and
computing a 2̂n-lift Tanner graph codeword comprising 2̂n-lift Tanner graph codeword bits on the 2̂n-lift Tanner graph using a 2̂n-lift graph edge configuration, the 2̂n−1 Tanner graph codeword, the 2̂n-lift Tanner graph information vector, and the 2̂n-lift Tanner graph parity check vector.

2. The method of claim 1, wherein the 2̂n-lift Tanner graph is constructed from the 2̂n−1 lift Tanner graph by:
incorporating a first copy of the 2̂n−1 lift Tanner graph into the 2̂n-lift Tanner graph;
incorporating a second copy of the 2̂n−1 lift Tanner graph into the 2̂n-lift Tanner graph; and
modifying a plurality of end points of at least one edge in the first copy or the second copy of the 2̂n−1 lift Tanner graph, wherein one or more edges has a first end point in the first copy of the 2̂n−1 lift Tanner graph and a second end point in the second copy of the 2̂n−1 lift Tanner graph.

3. The method of claim 2, further comprising setting at least one parity check bit on the 2̂n−1 lift Tanner graph of the 2̂n-lift Tanner graph as a binary summation of one parity check bit at one check node on the first copy of the 2̂n−1 lift Tanner graph and one parity check bit at one check node on the second copy of the 2̂n−1 lift Tanner graph.

4. The method of claim 2, further comprising:
calculating a parity check vector comprising parity check bits on the first copy of the 2̂n−1 lift Tanner graph using a 2̂n-lift Tanner graph edge configuration, the 2̂n−1 Tanner graph codeword, and the received 2̂n-lift Tanner graph parity check vector;
computing a codeword vector comprising codeword bits on the first copy of the 2̂n−1 lift Tanner graph using a calculated parity check vector on the first copy of the 2̂n−1 lift Tanner graph and the received information bits at variable nodes on the first copy of the 2̂n−1 Tanner graph;
computing a codeword vector comprising codeword bits for the second copy of the 2̂n−1 lift Tanner graph using calculated codeword vector on the 2̂n−1 Tanner graph of the 2̂n-lift Tanner graph and the codeword vector on the first copy of the 2̂n−1 lift Tanner graph; and
computing the codeword on the 2̂n-lift Tanner graph using the codeword vector on the first copy of 2̂n−1 lift Tanner graph and the codeword vector on the second copy of the 2̂n−1 lift Tanner graph.

5. The method of claim 4, wherein the codeword bits are equal to a received information bit at a variable node if the variable node receives only one information bit.

6. The method of claim 4, wherein the 2̂n−1 Tanner graph codeword and the 2̂n-lift Tanner graph information bits satisfy all parity check constraints on the first copy of the 2̂n−1 lift Tanner graph.

7. The method of claim 1, wherein the 2̂n-lift Tanner graph information vector comprises at most one information bit for each variable node in the 2̂n-lift Tanner graph.

8. The method of claim 1, wherein the 2̂n-lift Tanner graph parity check vector comprises one parity check bit for each check node in the 2̂n-lift Tanner graph.

9. The method of claim 1, further comprising computing one codeword bit for each variable node in the 2̂n-lift Tanner graph and wherein the computed codeword bit for each variable node is equal to a received information bit, if the variable node receives exactly one information bit.

10. The method of claim 9, wherein the one codeword bit for each variable node in the 2̂n−1 lift Tanner graph and the codeword bit for each variable node are equal to 2̂n−1 Tanner graph information bits at the variable node if exactly one information bit is calculated at the variable node.

11. The method of claim 1, wherein the 2̂n-lift Tanner graph codeword on the 2̂n-lift Tanner graph and the 2̂n-lift Tanner graph parity check bits satisfy parity check constraints on the 2̂n-lift Tanner graph.

12. The method of claim 1, wherein the codeword bits on the 2̂n−1 lift Tanner graph and the calculated parity check bits on the 2̂n−1 Tanner graph of the 2̂n-lift graph satisfy parity check constraints on the 2̂n−1 Tanner graph.

13. The method of claim 1, wherein calculating the 2̂n−1 Tanner graph information vector comprising information bits on the 2̂n−1 lift Tanner graph of the 2̂n-lift Tanner graph using the information bits of the received information vector comprises setting at least one information bit on the 2̂n−1 lift Tanner graph of the 2̂n-lift Tanner graph as a binary summation of one information bit at one variable node on a first copy of the 2̂n−1 lift Tanner graph and one information bit at one variable node on a second copy of the 2̂n−1 lift Tanner graph.

14. A non-transitory computer-readable storage medium comprising computer-executable instructions stored thereon which, in response to execution by a computer, cause the computer to perform the method of claim 1.

15. The computer-readable storage medium of claim 13, further comprising computer-executable instructions stored thereon which, in response to execution by the computer, cause the computer to perform the method that further includes:
passing messages from variable node units to check node units at a first time interval, and
passing the messages from the check node units to the variable node units at a second time interval to reduce a probability of memory conflicts.

16. A method to store data, comprising:
receiving the data to be encoded;
receiving a low density parity check (“LDPC”) code based on a Tanner graph G(k);
dividing the LDPC code a number of times into a data encoding on a smaller LDPC code graph G(k−n); and
encoding the data according to the data encoding on the smaller LDPC code graph G(k−n) to generate an encoded message.

17. The method of claim 16, wherein dividing the LDPC code the number of times into the data encoding on the smaller LDPC code graph comprises dividing the LDPC code until a size of a Tanner graph representing the LDPC code is suitable in connection with encoding according to encoding speed and complexity.

18. The method of claim 16, further comprising storing the encoded message in a multilayer cell memory.

19. The method of claim 16, wherein dividing the LDPC code the number of times into the data encoding on the smaller LDPC code graph comprises dividing the LDPC code based on the Tanner graph G(k) until a protograph G(0) is generated.

20. The method of claim 16, wherein the low density parity check code based on the Tanner graph G(k) comprises a 2-lift based LPDC code.

21. The method of claim 16, further comprising decoding the encoded message.

22. An encoder, comprising:
a covered codeword processor unit;
a modified codeword processor unit; and
a divide and conquer unit coupled to the covered codeword processor unit and to the modified codeword processor unit, the divide and conquer unit being operative to:
generate a first smaller sized problem instance,
receive a first solution output result from the covered codeword processor unit,
generate a second smaller sized problem instance by use of the received first solution output result,
receive a second solution output result from the modified codeword processor unit, and
generate a generalized codeword based on the received first solution output result and the received second solution output result;
wherein the covered codeword processor unit is operative to:
receive the generated first smaller sized problem instance from the divide and conquer unit,
generate the first solution output result based on the generalized first smaller sized problem instance, and
send the generated first solution output result to the divide and conquer unit; and
wherein the modified codeword processor unit is operative to:
receive the generated second smaller sized problem instance from the divide and conquer unit, and
generate the second solution output result based on the received second smaller sized problem instance.

23. The encoder of claim 22, further comprising a storage unit, coupled to the modified codeword processor unit, to store the generated second solution output result.

24. The encoder of claim 22, wherein the divide and conquer unit is operative to reduce a 2-lift graph to a base graph to generate the first smaller sized problem instance.

25. The encoder of claim 22, wherein the covered codeword processor unit is operative to:
determine variable nodes of a fiber of nodes of a 2-lift graph corresponding to information bits;
receive a generalized information vector comprising the information bits;
receive a generalized parity check vector;
calculate a covered information vector by use of the information bits of the received generalized information vector; and
calculate a covered codeword by use of the received generalized parity check vector and the covered information vector, wherein the calculated codeword vector represents the first solution output result.

26. The encoder of claim 25, wherein the modified codeword processor unit is operative to:
receive a covered generalized codeword on a base graph of the 2-lift graph;
receive an information vector on a first copy of the base graph of the 2-lift graph;
receive a parity check vector on a first copy of the base graph of the 2-lift graph;
calculate a plurality of crossing parameters by use of a 2-lift graph edge configuration;
calculate a modified parity check vector by use of a first copy of the base graph of the 2-lift graph and the calculated plurality of crossing parameters, and the received parity check vector; and
calculate a codeword by use of a first copy of the base graph of the 2-lift graph, the received information vector, and the calculated modified parity check vector, wherein the calculated codeword represents the second solution output result.
